(19) United States
(12) Patent Application Publication
(10) Pub. No.: US 2012/0187992 A1
(43) Pub. Date: Jul. 26, 2012

(54) CLOCK DELAY CIRCUIT

(75) Inventor: Jae Il KIM, Ichon-shi (KR)

(73) Assignee: Hynix Semiconductor Inc., Ichon-si (KR)

(21) Appl. No.: 13/188,651

(22) Filed: Jul. 22, 2011

(30) Foreign Application Priority Data
Jan. 25, 2011 (KR) 10-2011-0007292

(51) Int. Cl. H03L 7/08

(52) U.S. Cl. 327/158

(57) ABSTRACT

Various embodiments of a clock delay circuit may include a variable delay unit and a delay control unit. The variable delay unit may include a plurality of first unitary delay units and a plurality of second unitary delay units. The variable delay unit is configured to generate an output clock by delaying an input clock through the first unitary delay units or the first and second unitary delay units, according to the activation/deactivation of a pre-locking signal. The delay control unit is configured to detect a phase difference between the input clock and a feedback clock generated by delaying the output clock by a delay value of an internal clock path, adjust the delay values of the first and second unitary delay units according to the detected phase difference, and activate the pre-locking signal if the phase difference between the input clock and the feedback clock is within a predetermined range.

### CROSS-REFERENCES TO RELATED APPLICATION

The present application claims priority under 35 U.S.C. §119(a) to Korean Patent Application. No. 10-2011-0007292, filed on Jan. 25, 2011, in the Korean Intellectual Property Office, which is incorporated herein by reference in its entirety as if set forth in full.

### BACKGROUND

1. Technical Field

Various embodiments of the present invention relates to a semiconductor memory apparatus. In particular, certain embodiments relate to a scheme for controlling the phase of a clock in consideration of a delay value of an internal clock path.

2. Related Art

For an improved operation speed and an efficient internal operation, semiconductor apparatuses operate in synchronization with a reference periodic pulse signal such as a clock. Thus, most semiconductor apparatuses operate using an external clock or an internal clock.

An external clock signal inputted into a semiconductor apparatus may be delayed in the semiconductor apparatus. Therefore, if a delayed clock signal is used to output data, the output data may not be synchronized with the external clock signal. In order to obviate this problem, a semiconductor apparatus often uses a delay-locked loop (DLL) or a phase-locked loop (PLL) to compensate a timing difference between an external clock signal and an internal clock signal.

The delay-locked loop (DLL) uses a variable delay circuit to delay an input clock to generate an output clock. Here, the time necessary to generate the output clock with a desired phase depends on how to design and control the variable delay circuit. What is therefore required is a scheme for designing the variable delay circuit to efficiently delay the input clock to rapidly generate the output clock with a desired phase.

### SUMMARY

Accordingly, there is a need for a clock delay circuit for rapidly generating an output clock with a target phase.

To attain the advantages and in accordance with the purposes of the invention, as embodied and broadly described herein, one exemplary aspect of the present invention may provide a clock delay circuit which includes: a variable delay unit including a plurality of first delay units and a plurality of second delay units and configured to generate an output clock by passing an input clock through the first delay units or the first and second delay units, according to activation/deactivation of a pre-locking signal; and a delay control unit configured to detect a phase difference between the input clock and a feedback clock generated by delaying the output clock by a delay value of an internal clock path, adjust the delay values of the first and second delay units according to the detected phase difference, and activate the pre-locking signal if the detected phase difference between the input clock and the feedback clock is within a predetermined range.

In another exemplary aspect of the present invention, a clock delay circuit may include: first and second variable delay units including a plurality of first unitary delay units and a plurality of second unitary delay units and configured to delay an input clock through the first unitary delay units or the first and second unitary delay units, according to the activation/deactivation of a pre-locking signal; a phase mixing unit configured to output one of the output signals of the first and second variable delay units as an output clock or output the output clock by mixing the phases of the output signals of the first and second variable delay units, according to the is activation/deactivation of a post-locking signal; and a delay control unit configured to detect a phase difference between the input clock and a feedback clock generated by delaying the output clock by a delay value of an internal clock path, adjust the delay values of the first and second unitary delay units according to the detected phase difference, activate the pre-locking signal if the phase difference between the input clock and the feedback clock is within a first range, and activate the post-locking signal if the phase difference between the input clock and the feedback clock is within a second range narrower than the first range.

In another exemplary aspect of the present invention, a clock delay circuit may include: a variable delay unit including a plurality of unitary delay units having different delay values and configured to delay an input clock to generate an output clock; and a delay control unit configured to adjust a delay value of the variable delay unit such that the phase of the output clock precedes the phase of the input clock by an internal delay value of an internal clock path. The delay control unit detects a phase difference between the input clock and a feedback clock generated by delaying the output clock by the internal delay value, controls the unitary delay units, which have the greatest delay value among the unitary delay units, to delay a signal if the phase difference between the input clock and the feedback clock exceeds a first range, controls a combination of the unitary delay units, which have the greatest delay value among the unitary delay units, and the unitary delay units, which have the is smallest delay value among the unitary delay units, to delay a signal if the phase difference between the input clock and the feedback clock is within the first range, and performs a control operation to mix the phases of signals delayed by the unitary delay units if the phase difference between the input clock and the feedback clock is within a second range narrower than the first range.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate various embodiments consistent with the invention and, together with the description, serve to explain the principles of the invention.

FIG. 1 is a block diagram illustrating a clock delay circuit according to an exemplary embodiment of the present invention; and

FIG. 2 is a block diagram illustrating an exemplary embodiment of a delay control unit illustrated in FIG. 1.

### DETAILED DESCRIPTION

Reference will now be made in detail to the exemplary embodiments consistent with the present disclosure, examples of which are illustrated in the accompanying drawings. Wherever possible, the same reference characters will be used throughout the drawings to refer to the same or like parts.

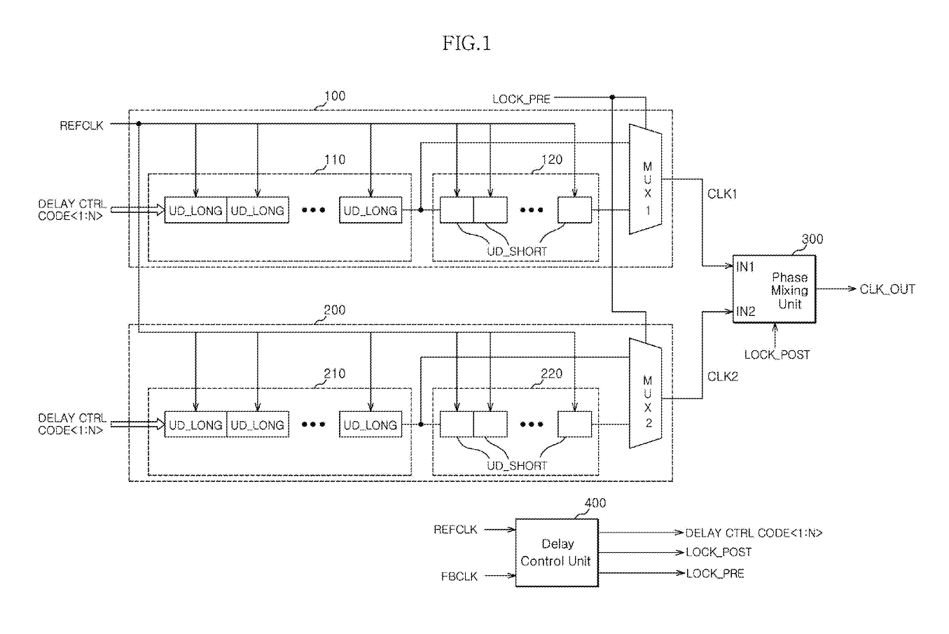

FIG. 1 is a block diagram illustrating a clock delay circuit according to an exemplary embodiment of the present invention.

Referring to FIG. 1, the clock delay circuit may include a variable delay unit 100/200/300 and a delay control unit 400.

The variable delay unit 100/200/300 may include a plurality of unitary delay units 110, 120, 210 and 220 which have different delay values. The variable delay unit 100/200/300 delays an input clock REFCLK to generate an output clock CLK_OUT. In an exemplary embodiment, the variable delay unit 100/200/300 includes a first variable delay unit 100, a second variable delay unit 200, and a phase mixing unit 300.

The first variable delay unit 100 may include a plurality of first unitary delay units 110, a plurality of second unitary delay units 120, and a selection unit MUX1. Here, a delay value of the first unitary delay unit UD_LONG may be designed to be greater than a delay value of the second unitary delay unit UD_SHORT. The first unitary delay units 110 and the second unitary delay units 120 of the first variable delay unit 100 are configured to adjust a delay value is according to a code value of a delay control code DELAY CTRL CODE<1: N>.

When a pre-locking signal LOCK_PRE is deactivated to a low level, the first variable delay unit 100 may use the first unitary delay units 110 to delay the input clock REFCLK; and when the pre-locking signal LOCK_PRE is activated to a high level, the first variable delay unit 100 may use the first unitary delay units 110 and the second unitary delay units 120 to delay the input clock REFCLK. Here, a signal outputted from the first variable delay unit 100 is referred to as a first output clock CLK1. That is, when the pre-locking signal LOCK_PRE is deactivated to a low level, the selection unit MUX1 uses the first unitary delay units 110 to output a delayed signal; and when the pre-locking signal LOCK_PRE is activated to a high level, the selection unit MUX1 uses the first unitary delay units 110 and the second unitary delay units 120 to output a delayed signal.

The second variable delay unit 200 may include a plurality of first unitary delay units 210, a plurality of second unitary delay units 220, and a selection unit MUX2. Here, a delay value of the first unitary delay unit UD_LONG may be designed to be greater than a delay value of the second unitary delay unit UD_SHORT. The first unitary delay units 210 and the second unitary delay units 220 of the second variable delay unit 200 are configured to adjust a delay value according to a code value of a delay control code DELAY CTRL CODE<1: N>.

When a pre-locking signal LOCK_PRE is deactivated to a low level, the second variable delay unit 200 may use the first unitary delay units 210 to delay the input clock REFCLK; and when the pre-locking signal LOCK_PRE is activated to a high level, the second variable delay unit 200 may use the first unitary delay units 210 and the second unitary delay units 220 to delay the input clock REFCLK. Here, a signal outputted from the second variable delay unit 200 is referred to as a second output clock CLK2. That is, when the pre-locking signal LOCK_PRE is deactivated to a low level, the selection unit MUX2 uses the first unitary delay units 210 to output a delayed signal; and when the pre-locking signal LOCK_PRE is activated to a high level, the selection unit MUX2 uses the first unitary delay units 210 and the second unitary delay units 220 to output a delayed signal.

For reference, the first output clock CLK1 outputted from the first variable delay unit 100 and the second output clock CLK2 outputted from the second variable delay unit 200 are designed to have a predetermined phase difference. In an exemplary embodiment, the phase difference between the first output clock CLK1 and the second output clock CLK2 is designed to correspond to the delay value of the first unitary delay unit UD_LONG or the delay value of the second unitary delay unit UD_SHORT. The phase difference between the first output clock CLK1 and the second output clock CLK2 may vary according to embodiments.

According to the activation/deactivation of a post-locking signal LOCK_POST, the phase mixing unit 300 outputs one of the first output clock CLK1 of the first variable delay unit 100 and the second is output clock CLK2 of the second variable delay unit 200 as the output clock CLK_OUT, or outputs the output clock CLK_OUT by mixing the phase of the first output clock CLK1 of the first variable delay unit 100 and the phase of the second output clock CLK2 of the second variable delay unit 200. That is, in an exemplary embodiment, when the post-locking signal LOCK_POST is deactivated to a low level, the phase mixing unit 300 outputs one of the first output clock CLK1 and the second output clock CLK2 as the output clock CLK_OUT; and when the post-locking signal LOCK_POST is activated to a high level, the phase mixing unit 300 outputs the output clock CLK_OUT by mixing the phase of the first output clock CLK1 and the phase of the second output clock CLK2. For reference, the case of mixing the phase of the first output clock CLK1 and the phase of the second output clock CLK2 can adjust the delay value of the output clock CLK_OUT more accurately than the case of not mixing the phase of the first output clock CLK1 and the phase of the second output clock CLK2 can adjust the delay value of the output clock CLK_OUT.

The delay control unit 400 adjusts the delay values of the variable delay unit 100/200/300 so that the phase of the output clock CLK_OUT precedes the phase of the input clock REFCLK by an internal delay value of an internal clock path. That is, the delay control unit 400 detects a phase difference between the input clock REFCLK and a feedback clock FBCLK generated by delaying the output clock CLK_OUT by the internal delay value of the internal clock path. If the phase difference between the input clock REFCLK and is the feedback clock FBCLK exceeds the first range, the delay control unit 400 controls the unitary delay units 110 and 210 (which have the greatest delay value among the unitary delay units) to delay a signal.

If the phase difference between the input clock REFCLK and the feedback clock FBCLK is within the first range, the delay control unit 400 controls a combination of the unitary delay units 110 and 210 (which have the greatest delay value among the unitary delay units) and the unitary delay units 120 and 220 (which have the smallest delay value among the unitary delay units) to delay a signal.

If the phase difference between the input clock REFCLK and the feedback clock FBCLK is within a second range narrower than the first range, the delay control unit 400 controls the phase mixing unit 300 to mix the phases of the output clocks CLK1 and CLK2 delayed by the unitary delay units. That is, the delay control unit 400 controls the phase mixing unit 300 to mix the phase of the first output clock CLK1 of the first variable delay unit 100 and the phase of the second output clock CLK2 of the second variable delay unit 200. Here, the first output clock CLK1 of the first variable delay unit 100 and the second output clock CLK2 of the second variable delay unit 200 are set to have a predetermined phase difference. In an exemplary embodiment, the first output clock CLK1 and the second output clock CLK2 are set to have a phase difference corresponding to the delay value of the first unitary delay unit UD_LONG or the delay value of the second unitary delay unit UD_SHORT.

That is, the delay control unit 400 detects a phase is difference between the input clock REFCLK and the feedback clock FBCLK feedback clock FBCLK generated by delaying the output clock CLK_OUT by the internal delay value of the internal clock path, and adjusts the delay values of the first and second unitary delay units according to the detection result. If the phase difference between the input clock REFCLK and the feedback clock FBCLK is within the first range, the delay control unit 400 activates the pre-locking signal LOCK_PRE to a high level; and if the phase difference between the input clock REFCLK and the feedback clock FBCLK is within the second range narrower than the first range, the delay control unit 400 activates the post-locking signal LOCK_POST to a high level.

Consequently, according to the phase difference between the input clock REFCLK and the feedback clock FBCLK, the delay control unit 400 controls the variable delay unit 100/200/300 through three steps to adjust the phase of the output clock CLK_OUT.

In the first step, if the phase difference between the input clock REFCLK and the feedback clock FBCLK is greatest, that is, if the phase difference between the input clock REFCLK and the feedback clock FBCLK exceeds the first range, the delay control unit 400 uses the first unitary delay units UD_LONG (which have the greatest delay value among the unitary delay units) so that the phase difference between the input clock REFCLK and the feedback clock FBCLK is within the first range. Because the first unitary delay units UD_LONG having the greatest delay value are used, the phase difference between the input clock REFCLK and the feedback clock FBCLK is rapidly reaches a value within the first range.

In the second step, if the phase difference between the input clock REFCLK and the feedback clock FBCLK is within the first range, the delay control unit 400 uses the first unitary delay units UD_LONG and the second unitary delay units UD_SHORT (which have a smaller delay value than the first unitary delay units UD_LONG) so that the phase difference between the input clock REFCLK and the feedback clock FBCLK is within the second range narrower than the first range. Because both the first unitary delay units UD_LONG and the second unitary delay units UD_SHORT are used, the delay value can be adjusted more accurately.

In the third step, if the phase difference between the input clock REFCLK and the feedback clock FBCLK is within the second range, the delay control unit 400 uses the first unitary delay units UD_LONG and the second unitary delay units UD_SHORT (which have a smaller delay value than the first unitary delay units UD_LONG) so that the input clock REFCLK and the feedback clock FBCLK have the same phase. At this point, the delay control unit 400 uses the phase mixing unit 300 to mix signals. The third step can adjust the delay value more accurately than the first step and the second step.

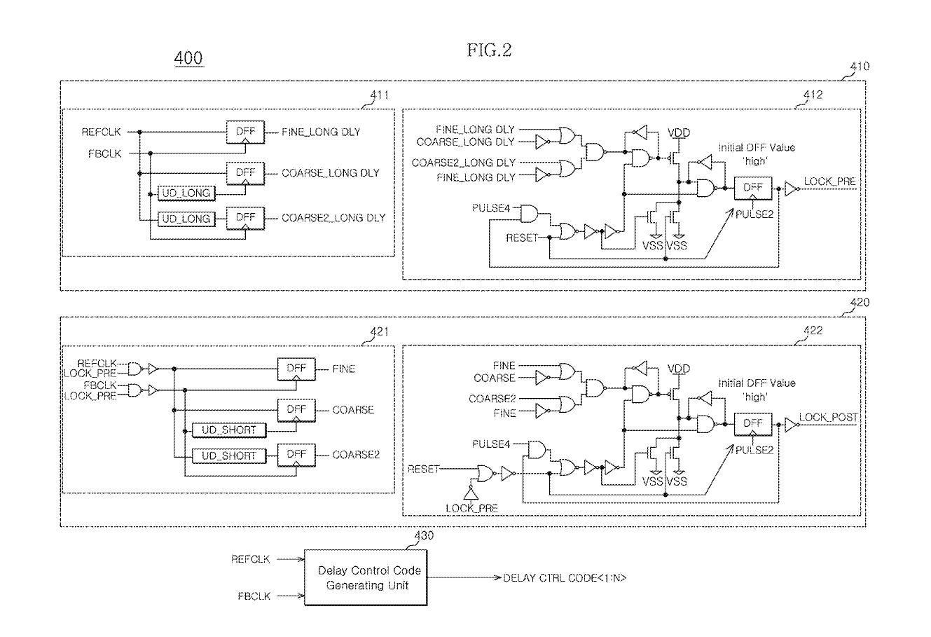

FIG. 2 is a block diagram illustrating an exemplary embodiment of the delay control unit 400 illustrated in FIG. 1.

Referring to FIG. 2, the delay control unit 400 may include a pre-locking signal generating unit 410, a post-locking signal generating unit 420, and a delay control code generating unit 430.

The pre-locking signal generating unit 410 activates the pre-locking signal LOCK_PRE to a high level if the phase difference between the input clock REFCLK and the feedback clock FBCLK is within the first range. In an exemplary embodiment, the pre-locking signal generating unit 410 includes a first phase detecting unit 411 and a first signal outputting unit 412. The first phase detecting unit 411 outputs a plurality of first phase detection signals FINE_LONG DLY, COARSE_LONG DLY and COARSE2_LONG DLY by comparing the input clock REFCLK and the feedback clock FBCLK and the signals generated by delaying the input clock REFCLK and the feedback clock FBCLK by a first delay value. The first phase detecting unit 411 detects whether the phase difference between the input clock REFCLK and the feedback clock FBCLK is within the first range. The first signal outputting unit 412 selectively activates the pre-locking signal LOCK_PRE in response to the first phase detection signals FINE_LONG DLY, COARSE_LONG DLY and COARSE2_LONG DLY, a plurality of control pulse signals PULSE2 and PULSE4, and a reset signal RESET. Here, the control pulse signals PULSE2 and PULSE4 and the reset signal RESET are defined as pulse signals that pulse in a predetermined period.

The post-locking signal generating unit 420 activates the post-locking signal LOCK_POST if the phase difference between the input clock REFCLK and the feedback clock FBCLK is within the second range, after the pre-locking signal LOCK_PRE is activated. In an exemplary embodiment, the post-locking signal generating unit 420 includes a second phase detecting unit 421 and a second signal outputting unit 422. The second phase detecting unit 421 outputs a plurality of second phase detection signals FINE, COARSE and COARSE2 by comparing the pre-locking signal LOCK_PRE and the input clock REFCLK and the feedback clock FBCLK and the signals generated by delaying the input clock REFCLK and the feedback clock.

FBCLK by a second delay value smaller than the first delay value. The second phase detecting unit 421 detects whether the phase difference between the input clock REFCLK and the feedback clock FBCLK is within the second range. The second signal outputting unit 422 selectively activates the post-locking signal LOCK_POST in response to the second phase detection signals FINE, COARSE and COARSE2, the control pulse signals PULSE2 and PULSE4, and the reset signal RESET. Here, the control pulse signals PULSE2 and PULSE4 and the reset signal RESET are defined as pulse signals that pulse in a predetermined period.

The delay control code generating unit 430 detects the phase difference between the input clock REFCLK and the feedback clock FBCLK, and adjusts the code value of the delay control code DELAY CTRL CODE<1: N> according to the detection result.

The delay control code generating unit 430 adjusts the code value of the delay control code DELAY CTRL CODE<1: N> until the input clock REFCLK and the feedback clock FBCLK have the same phase. The code value of the delay control code DELAY CTRL CODE<1: N> is fixed when the input clock REFCLK and the feedback is clock FBCLK have the same phase. This state is referred to as a final locking state.

As described above, the clock delay circuit according to the embodiments of the present invention can rapidly generate the output clock CLK_OUT by efficiently controlling the variable delay unit 100/200/300. That is, the present invention can reduce the time taken to reach the final locking state. Also, the present invention can reduce the noise that may be generated when mixing the phases of the first output clock CLK1 and the second output clock CLK2 generated by the first unitary delay unit UD_LONG and the second unitary delay unit UD_SHORT that have different delay values.

While certain embodiments have been described above, it will be understood to those skilled in the art that the embodiments described are by way of example only. Accordingly, the clock delay circuit described herein should not be limited based on the described embodiments. Rather, the clock delay circuit described herein should only be limited in light of the claims that follow when taken in conjunction with the above description and accompanying drawings.

What is claimed is:

1. A clock delay circuit comprising:
a variable delay unit including a plurality of first delay units and a plurality of second delay units and configured to generate an output clock by passing an input clock through the first delay units or the first and second delay units, according to activation/deactivation of a pre-locking signal; and
a delay control unit configured to detect a phase difference between the input clock and a feedback clock generated by delaying the output clock by a delay value of an internal clock path, adjust the delay values of the first and second delay units according to the detected phase difference, and activate the pre-locking signal if the detected phase difference between the input clock and the feedback is clock is within a predetermined range.

2. The clock delay circuit according to claim 1, wherein a delay value of each of the plurality of first delay units is greater than a delay value of each of the plurality of second delay units.

3. The clock delay circuit according to claim 1, wherein the delay control unit comprises:
a delay control code generating unit configured to detect the phase difference between the input clock and the feedback clock and adjust a code value of a delay control code according to the detected phase difference;
a phase detecting unit configured to output a plurality of phase detection signals by comparing the input clock and the feedback clock and signals generated by delaying the input clock and the feedback clock by a first delay value; and
a signal outputting unit configured to selectively activate and output the pre-locking signal in response to the phase detection signals, a plurality of control pulse signals, and a reset signal.

4. A clock delay circuit comprising:
first and second variable delay units including a plurality of first unitary delay units and a plurality of second unitary delay units and configured to delay an input clock through the first unitary delay units or the first and second unitary delay units, according to the is activation/deactivation of a pre-locking signal;
a phase mixing unit configured to output one of the output signals of the first and second variable delay units as an output clock or output the output clock by mixing the phases of the output signals of the first and second variable delay units, according to the activation/deactivation of a post-locking signal; and
a delay control unit configured to detect a phase difference between the input clock and a feedback clock generated by delaying the output clock by a delay value of an internal clock path, adjust the delay values of the first and second unitary delay units according to the detected phase difference, activate the pre-locking signal if the phase difference between the input clock and the feedback clock is within a first range, and activate the post-locking signal if the phase difference between the input clock and the feedback clock is within a second range narrower than the first range.

5. The clock delay circuit according to claim 4, wherein the output signal of the first variable delay unit and the output signal of the second variable delay unit have a predetermined phase difference.

6. The clock delay circuit according to claim 4, wherein a delay value of each of the plurality of first unitary delay units is greater than a delay value of each of the plurality of second unitary delay units.

7. The clock delay circuit according to claim 4, wherein the delay control unit comprises:
a pre-locking signal generating unit configured to activate the pre-locking signal if the phase difference between the input clock and the feedback clock is within the first range;
a post-locking signal generating unit configured to activate the post-locking signal if the phase difference between the input clock and the feedback clock is within the second range, after the pre-locking signal is activated; and
a delay control code generating unit configured to detect the phase difference between the input clock and the feedback clock and adjust a code value of a delay control code according to the detected phase difference.

8. The clock delay circuit according to claim 7, wherein the pre-locking signal generating unit comprises:
a first phase detecting unit configured to output a plurality of first phase detection signals by comparing the input clock and the feedback clock and signals generated by delaying the input clock and the feedback clock by a first delay value; and
a first signal outputting unit configured to selectively activate and output the pre-locking signal in response to the first phase detection signals, a plurality of control pulse signals, and a reset signal.

9. The clock delay circuit according to claim 8, wherein the post-locking signal generating unit comprises:
a second phase detecting unit configured to output a plurality of second phase detection signals by comparing the input clock and the feedback clock and signals generated by delaying the input clock and the feedback clock by a second delay value smaller than the first delay value; and
a second signal outputting unit configured to selectively activate and output the post-locking signal in response to the second phase detection signals, the control pulse signals, and the reset signal.

10. A clock delay circuit comprising:
a variable delay unit including a plurality of unitary delay units having different delay values and configured to delay an input clock to generate an output clock; and
a delay control unit configured to adjust a delay value of the variable delay unit such that the phase of the output clock precedes the phase of the input clock by an internal delay value of an internal clock path,
wherein the delay control unit detects a phase difference between the input clock and a feedback clock generated by delaying the output clock by the internal delay value, controls the unitary delay units, which have the greatest delay value among the unitary is delay units, to delay a signal if the phase difference between the input clock and the feedback clock exceeds a first range, controls a combination of the unitary delay units, which have the greatest delay value among the unitary delay units, and the unitary delay units, which have the smallest delay value among the unitary delay units, to delay a signal if the phase difference between the input clock and the feedback clock is within the first range, and performs a control operation to mix the phases of signals delayed by the unitary delay units if the phase difference between the input clock and the feedback clock is within a second range narrower than the first range.

11. The clock delay circuit according to claim 10, wherein the first range is the delay value of the unitary delay unit having the greatest delay value.

12. The clock delay circuit according to claim 11, wherein the second range is the delay value of the unitary delay unit having the smallest delay value.
